(19) United States
(12) Patent Application Publication
(10) Pub. No.: US 2007/0184634 A1
(43) Pub. Date: Aug. 9, 2007

(54) Method of manufacturing a semiconductor device

(75) Inventors: Shinya Suzuki, Nanae (JP); Toshiaki Sawada, Nanae (JP); Masatoshi Iwasaki, Nanae (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/649,297

(22) Filed: Jan. 4, 2007

(30) Foreign Application Priority Data
Feb. 8, 2006 (JP) 2006-30756

(51) Int. Cl. H01L 21/00

(52) U.S. Cl. 438/460; 438/462

(57) ABSTRACT

A semiconductor device manufacturing method is disclosed wherein a semiconductor integrated circuit is formed in each of plural semiconductor chip regions of a semiconductor wafer which regions are to become semiconductor chips later and then the semiconductor wafer is cut along scribing regions each provided between adjacent semiconductor chip regions. The semiconductor chip regions are each in a rectangular shape having long sides and short sides. The scribing regions include a first scribing region in contact with the short sides and a second scribing region in contact with the long sides. The width of the second scribing region is smaller than the width of the first scribing region. In a photolithography process, first and second alignment patterns for making alignment in both X and Y directions are all formed in the first scribing region and not formed in the second scribing region. Both improvement of the alignment accuracy and reduction of the semiconductor device manufacturing cost can be attained.

### CROSS-REFERENCE TO RELATED APPLICATION

The present application claims priority from Japanese patent application No. 2006-30756 filed on Feb. 8, 2006, the content of which is hereby incorporated by reference into this application.

### BACKGROUND OF THE INVENTION

The present invention relates to a method of manufacturing a semiconductor device. Particularly, the present invention is concerned with a technique applicable effectively to the manufacture of a semiconductor device wherein semiconductor integrated circuits are formed on a semiconductor wafer with use of a photlithography process or the like and then the semiconductor wafer is cut along scribing regions.

By forming semiconductor integrated circuits respectively in plural semiconductor chip regions arranged in a lattice shape on a semiconductor wafer and cutting the semiconductor wafer along scribing regions between adjacent semiconductor chip regions on the wafer there are formed individual semiconductor chips each constituted by an individual semiconductor chip region.

In Japanese Unexamined Patent Publication No. Sho 63 (1988)-250119 (Patent Literature 1) there is described a technique associated with a semiconductor device having plural rectangular semiconductor chips arranged in a matrix shape on a semiconductor wafer and scribing lines which divide the semiconductor chips in a matrix shape. According to this technique, the scribing line width between short sides of adjacent such semiconductor chips is larger than that between long sides of the adjacent semiconductor chips, and a pattern for alignment and TEG are arranged on the scribing line between the short sides.

In Japanese Unexamined Patent Publication No. 2001-250800 (Patent Literature 2) there is described a technique wherein slits are formed along scribing lines on a semiconductor wafer with use of a cutting edge having an edge width larger than the width of a test pattern on the semiconductor wafer and then the interiors of the slits are cut in with a cutting edge having a small edge thickness to effect cutting along the slits.
[Patent Literature 1]
Japanese Unexamined Patent Publication
No. Sho 63 (1988)-250119
[Patent Literature 2]
Japanese Unexamined Patent Publication
No. 2001-250800

### SUMMARY OF THE INVENTION

Studies made by the present inventors have revealed the following fact.

Plural photolithography processes are performed for forming semiconductor integrated circuits in plural semiconductor chip regions on a semiconductor wafer. In an exposure step in each photolithography process, a pattern of a photomask (reticle) is reduced and projected onto a main surface of a semiconductor wafer, whereby a circuit pattern corresponding to the pattern of the photomask is baked to a photoresist film on the semiconductor wafer. In case of using a stepper, a photomask pattern as one unit is projected and exposed to a semiconductor wafer by one shot exposure. This is performed repeatedly while stepping the semiconductor wafer and the whole of a main surface of the semiconductor wafer is exposed by plural shots.

In an exposure step in each photolithography process it is necessary to perform an alignment operation for superimposing a pattern to be formed next exactly on a pattern already formed on a main surface of the semiconductor wafer, thereby preventing an alignment error of the resulting photoresist pattern.

Therefore, in a photolithography process, an alignment pattern is formed in a scribing region between adjacent semiconductor chips and is used for alignment in the exposure step in the next photolithography process, whereby a photomask pattern can be superimposed exactly on the pattern in each semiconductor chip region and hence it is possible to prevent an alignment error of the resulting photoresist pattern.

With the recent microstructurization and high integration of semiconductor devices, it is required to enhance the alignment accuracy in the exposure step. In this connection, it is preferable to perform alignment in two directions orthogonal to each other in the exposure step. As a result, the alignment accuracy is improved, which is advantageous to the microstructurization and high integration of semiconductor devices. Besides, it is possible to improve the semiconductor device manufacturing yield. Therefore, it is preferable that two types of alignment patterns be formed in scribing regions in order to effect alignment in two directions orthogonal to each other.

On the other hand, for reducing the semiconductor device manufacturing cost it is desired to increase the number of semiconductor chips capable of being obtained from one semiconductor wafer. Scribing regions are unnecessary regions for semiconductor chips themselves, so by reducing the width of each scribing region it is possible to increase the number of semiconductor chips capable of being obtained from one semiconductor wafer. However, if the width of each scribing region is made larger in order to form alignment patterns, the number of semiconductor chips capable of being obtained from one semiconductor wafer decreases, resulting in increase of the semiconductor device manufacturing cost.

It is an object of the present invention to provide a technique able to attain both improvement of the alignment accuracy and reduction of the semiconductor device manufacturing cost.

The above and other objects and novel features of the present invention will become apparent from the following description and the accompanying drawings.

The following is an outline of typical modes of the present invention as disclosed herein.

According to the present invention, two types of alignment patterns are used in a photolithography process, the two types of alignment patterns being formed in a first scribing region extending in a first direction and not formed in a second scribing region extending in a second direction intersecting the first direction.

According to the present invention, alignment is performed in two directions in a photolithography process and two types of alignment patterns for performing the alignment in the two directions are formed in a scribing region extending in a first direction and not formed in a second scribing region extending in a second direction intersecting the first direction.

The following is a brief description of an effect obtained by the typical modes of the present invention as disclosed herein.

It is possible to effect both improvement of the alignment accuracy and reduction of the semiconductor device manufacturing cost.

### BRIEF DESCRIPTION OF THE DRAWINGS

FIG. 1 is a manufacturing process flow chart showing a semiconductor device manufacturing process according to a first embodiment of the present invention;

FIG. 2 is a conceptual plan view of a semiconductor wafer in the semiconductor device manufacturing process according to the first embodiment;

FIG. 3 is a plan view of a principal portion of the semiconductor wafer in the semiconductor device manufacturing process according to the first embodiment;

FIG. 4 is a plan view of a principal portion of the semiconductor wafer, showing an alignment pattern-formed area and the vicinity thereof on a larger scale;

FIG. 5 is a sectional view of a principal portion in the semiconductor device manufacturing process according to the first embodiment;

FIG. 6 is a sectional view of the principal portion in the semiconductor device manufacturing process which follows FIG. 5;

FIG. 7 is a plan view showing an area which is exposed by one shot in an exposure step in a photolithography process;

FIG. 8 is a plan view of a principal portion of a semiconductor wafer in a semiconductor device manufacturing process as a comparative example;

FIG. 9 is a plan view of a principal portion of the semiconductor wafer in the comparative semiconductor device manufacturing process;

FIG. 10 is a manufacturing process flow chart showing a dicing process for a semiconductor wafer;

FIG. 11 is an explanatory diagram of the wafer dicing process;

FIG. 12 is an explanatory diagram of the wafer dicing process;

FIG. 13 is an explanatory diagram of the wafer dicing process;

FIG. 14 is an explanatory diagram of the wafer dicing process;

FIG. 15 is an explanatory diagram of the water dicing process;

FIG. 16 is a plan view showing a mounted state of a semiconductor chip to an LCD panel;

FIG. 17 is a sectional view of a principal portion, showing a mounted state of the semiconductor chip to the LCD panel;

FIG. 18 is a plan view of a principal portion of a semiconductor wafer in a semiconductor device manufacturing process according to another embodiment of the present invention;

FIG. 19 is a plan view of a principal portion of the semiconductor wafer, showing an alignment pattern-formed area and the vicinity thereof on a larger scale;

FIG. 20 is a plan view of a principal portion of a semiconductor wafer in a semiconductor device manufacturing process according to a further embodiment of the present invention; and

FIG. 21 is a plan view of a principal portion of another semiconductor wafer in the semiconductor device manufacturing process according to the further embodiment.

### DETAILED DESCRIPTION OF PREFERRED EMBODIMENTS

Where required for convenience' sake, the following embodiments will each be described in a divided manner into plural sections or embodiments, but unless otherwise mentioned, they are not unrelated to each other, but are in a relation such that one is a modification or a detailed or supplementary explanation of part or the whole of the other. In the following embodiments, when reference is made to the number of elements (including the number, numerical value, quantity and range), no limitation is made to the number referred to, but numerals above and below the number referred to will do as well unless otherwise mentioned and except the case where it is basically evident that limitation is made to the number referred to. Further, it goes without saying that in the following embodiments their constituent elements (including constituent steps) are not always essential unless otherwise mentioned and except the case where they are considered essential basically obviously. Likewise, it is to be understood that when reference is made to the shapes and positional relation of constituent elements in the following embodiments, those closely similar to or resembling such shapes, etc. are also included unless otherwise mentioned and except the case where a negative answer is evident basically. This is also true of the foregoing numerical value and range.

Embodiments of the present invention will be described in detail hereinunder with reference to the accompanying drawings. In all of the drawings for illustrating the embodiments, portions having the same functions are identified by like reference numerals, and repeated explanations thereof will be omitted. In the following embodiments, explanations of the same or similar portions will not be repeated in principle except where such explanations are specially required.

Further, in the drawings used in the embodiments, even sectional or plan views may be hatched to make them easier to see.

### First Embodiment

A semiconductor device manufacturing method according to a first embodiment of the present invention will be described below with reference to drawings.

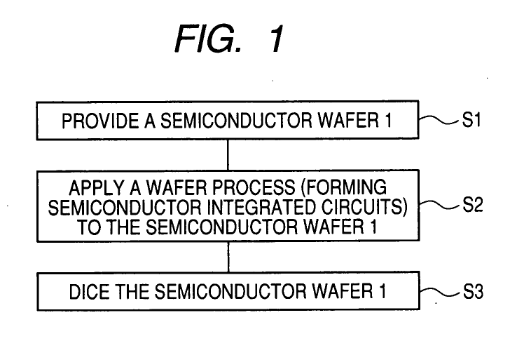

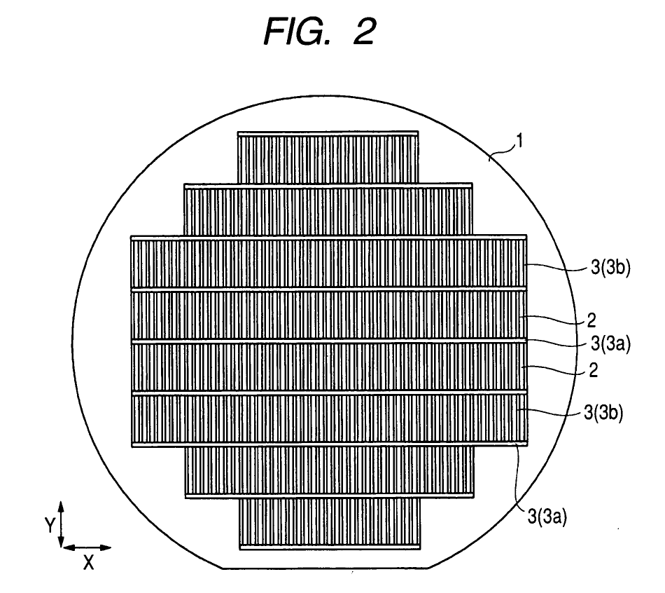

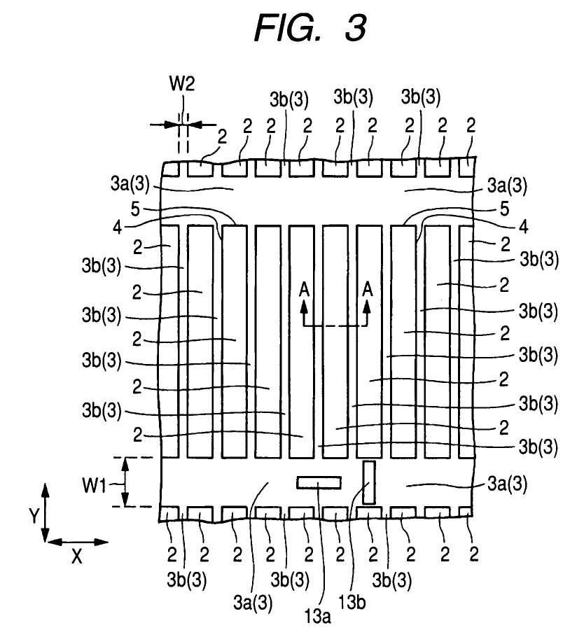

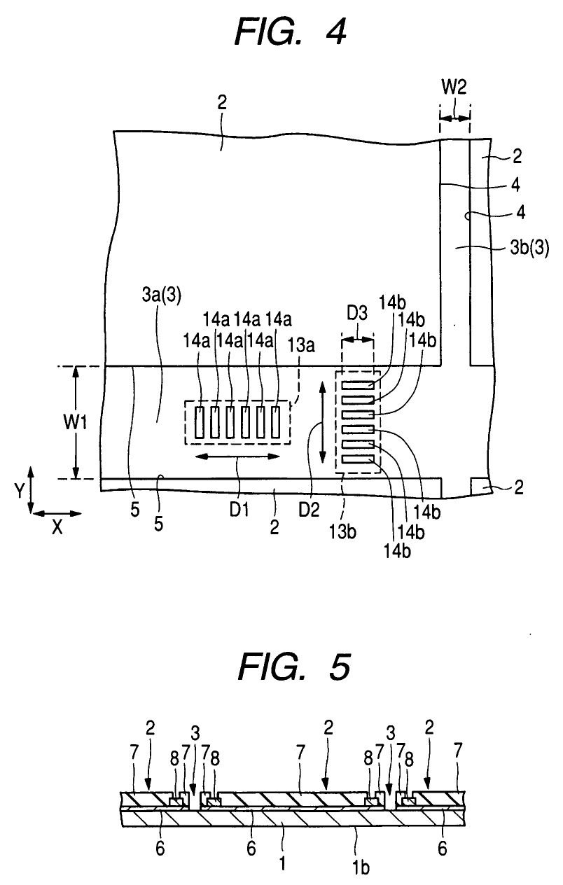

FIG. 1 is a manufacturing process flow chart showing a semiconductor device manufacturing process (manufacturing method) according to a first embodiment of the present invention, FIG. 2 is a conceptual plan view (entire plan view) of a semiconductor wafer in the semiconductor device manufacturing process (during a wafer process or after the wafer process and before dicing) according to this embodiment, FIG. 3 is a plan view (a partial enlarged plan view) of a principal portion thereof, FIG. 4 is a plan view (a partial enlarged plan view) of a principal portion of the semiconductor wafer, showing an alignment pattern-formed area and the vicinity thereof on a larger scale, and FIG. 5 is a sectional view of a principal portion of the semiconductor wafer in the semiconductor device manufacturing process (after the wafer process and before dicing) according to this embodiment. In FIG. 5, the area corresponding to line A-A in FIG. 3 is shown as a sectional view.

First, a semiconductor wafer (semiconductor substrate) 1 is provided (step S1). For example, the semiconductor wafer 1 is formed of a single crystal silicon and is generally circular in plan. Then, the semiconductor wafer 1 is subjected to a wafer process (step S2). The wafer process is also called a preprocess and generally involves the steps of forming various semiconductor elements or semiconductor integrated circuits on a main surface of a surface layer portion of the semiconductor wafer 1, forming a wiring layer (and pad electrodes), forming a surface protecting film, and thereafter creating a state in which an electric test for each of plural semiconductor chip regions 2 formed on the semiconductor wafer can be conducted using a probe or the like.

As shown in FIGS. 2 to 5, the main surface of the semiconductor wafer 1 has plural semiconductor chip regions (semiconductor element-formed regions, unit integrated circuit-formed regions) 2 and scribing regions (scribing lines) 3 each formed between adjacent semiconductor chip regions 2. The semiconductor chip regions 2 correspond to regions which become individual semiconductor chips (corresponding to semiconductor chips 12 to be described later) when the semiconductor wafer 1 is diced in a dicing process to be described later. The semiconductor chip regions 2 are disposed (arranged) regularly in two dimensions (in X and Y directions) on the main surface of the semiconductor wafer 1. The semiconductor chip regions 2 have the same size (planar shape) and structure and are each in a quadrangular (rectangular in the illustrated example) plane shape having long sides 4 and short sides 5 shorter than the long sides 4. The scribing regions 3 are each a region sandwiched in between adjacent semiconductor chip regions 2, i.e., a region located between adjacent semiconductor chip regions 2, and are present in a lattice shape with respect to the main surface of the semiconductor wafer 1. In other words, the regions (semiconductor element- or semiconductor integrated circuit-formed regions) surrounded by the scribing regions correspond to the semiconductor chip regions 2. In a dicing process which will be described later, the semiconductor wafer 1 is cut or diced along the scribing regions 3.

In the sectional view of FIG. 5 there is shown a completed state of the wafer process of step S2. In FIG. 5, semiconductor integrated circuit regions (semiconductor element-formed regions) 6 are shown on the semiconductor wafer 1 as semiconductor element-, interlayer insulating film- and wiring layer-formed regions, i.e., semiconductor integrated circuit-formed regions, and a protective film (insulating film, passivation film) 7 for surface protection is formed on each of the semiconductor integrated circuit regions 6. Each integrated circuit region 6 and each protective film 7 are formed in each semiconductor chip region 2 on the semiconductor wafer 1 and not formed on each scribing region 3. Apertures are formed in the protective films 7 and pad electrodes (bonding pads, electrode pads) 8 are exposed from the apertures. The pad electrodes 8, though not shown in FIGS. 2 to 4, are arranged plurally near and along the long sides 4 of the semiconductor chip regions 2 and are electrically connected via wiring layers (internal wiring layers) to semiconductor integrated circuits (semiconductor elements) formed in the semiconductor chip regions 2. Bump electrodes may be formed on the pad electrodes 8.

In the wafer process of step S2, semiconductor integrated circuits are formed respectively in the semiconductor chip regions 2 on the main surface of the semiconductor wafer 1. More specifically, in step S2, a semiconductor element (e.g., transistor), an interlayer insulating film, a wiring layer (i.e., a semiconductor integrated circuit region 6) and further a protective film 7 are formed in each semiconductor chip region 2 on the main surface of the semiconductor wafer 1. Thus, the step S2 can be regarded as being a process of forming semiconductor integrated circuits respectively in the plural semiconductor chip regions 2 on the semiconductor wafer 1 which regions are to be later divided into individual semiconductor chips 12. It is preferable that the protective film 7 be formed in each semiconductor chip region 2 but not formed in each scribing region 3, whereby the cutting of the semiconductor wafer 1 can be done more easily in a wafer dicing process which will be described later.

The semiconductor chip regions 2 each correspond up to the region where the protective film 7 used generally as a passivation film is formed. In the case where the passivation film (protective film 7) is not formed, the semiconductor chip regions 2 each correspond up to the region where a surface electrode formed of aluminum for example. Each scribing region 3 corresponds to the region between adjacent semiconductor chip regions 2 and therefore corresponds substantially to the region from an end of the protective film in a semiconductor chip region 2 up to an end of the protective film 7 in an semiconductor region 2.

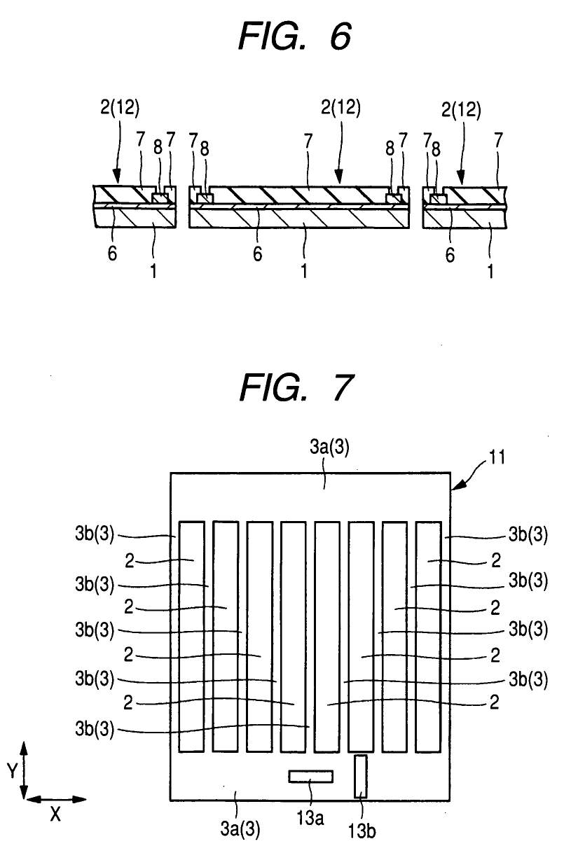

Next, where required, the semiconductor wafer 1 is subjected to back grinding for grinding a back surface hereof (a main surface on the side opposite to the main surface on the semiconductor element- or semiconductor integrated circuit-formed side) and inspection, then is diced (cut) into individual semiconductor chips 12 (step S3). FIG. 6 is a sectional view of a principal portion in the semiconductor device manufacturing process which follows FIG. 5, showing a diced state of the semiconductor wafer 1. In FIG. 6 there are shown regions corresponding to FIG. 6.

In the dicing process of step S3 for the semiconductor wafer 1, though the details thereof will be described later, the semiconductor wafer 1 is cut (diced) along the scribing regions 3 each formed between adjacent semiconductor chip regions 2 with use of a dicing blade rotating at high speed. As a result of dicing, as shown in FIG. 6, the semiconductor wafer 1 is separated (divided) into individual semiconductor chip regions 2, affording individual semiconductor chips 12. That is, the semiconductor chip regions 2 become the semiconductor chips 12 respectively. Since each semiconductor chip region 2 is rectangular in shape as described above, the outline of each semiconductor chip 12 is also in a rectangular shape having long sides 4 and short sides 5.

In this way there is manufactured a semiconductor device as the semiconductor chip 12. Invalid chips (invalid semiconductor chips) formed in the peripheral portion of the semiconductor wafer 1 and not having a complete structure as a semiconductor chip are removed after the dicing process. After the dicing process of step S3, the other normal semiconductor chips 12 are conveyed as effective chips to the next process, e.g., inspection process or die bonding process.

The above wafer process of step S2 includes plural photolithography processes. Each photolithography process comprises a step of forming (applying) a photoresist film onto the semiconductor wafer 1, a step of exposing the photoresist film, and a step of developing the exposed photoresist film to form a photoresist pattern (a patterned photoresist film). The photoresist pattern formed by the photolithography process is used, for example, as an etching mask for processing (patterning) conductive films and insulating films formed on the semiconductor wafer 1 or as an ion implantation preventing mask.

In the exposure step in each photolithography process there is used an exposure device (e.g., stepper) to reduce a photomask (reticle) pattern and project (radiate, transfer) it onto the main surface of the semiconductor wafer 1, whereby a pattern (circuit pattern) corresponding to the photomask (reticle) pattern is baked to the photoresist film. The photomask (reticle) is formed with patterns corresponding to photoresist patterns to be formed in the semiconductor regions 2 and patterns corresponding to alignment patterns to be formed in the scribing regions. In case of using a stepper (a stepping type projection exposure device) as the exposure device, the photomask (reticle) pattern is projected and exposed as one unit (shot unit) to the semiconductor wafer 1 by one-shot (a single radiation of exposure light) exposure and this is repeated while stepping the semiconductor wafer 1. In this way the entire main surface of the semiconductor wafer 1 is exposed by plural shots.

As described above, the wafer process of step S2 includes plural photolithography processes. In this case, the semiconductor wafer 1 is exposed using patterns different for each photolithography process. In the exposure step in each photolithography process there is performed an alignment (positioning) operation such that a pattern (photomask pattern) to be formed next is superimposed exactly (is brought into an optimum relative positional relation) on a pattern (a pattern in each semiconductor region 2) already formed on the main surface of the semiconductor wafer 1, whereby it is necessary to prevent an alignment error of the photoresist pattern formed on the main surface of the semiconductor wafer 1. By forming an alignment pattern in a scribing region 3 between semiconductor chip regions 2 and using this alignment pattern in the exposure step in the next photolithography process it is possible to superimpose the photomask pattern exactly onto the pattern in each semiconductor region 2 and hence possible to prevent an alignment error of the photoresist pattern formed on the main surface of the semiconductor wafer 1. In case of using a stepper (a stepping type projection exposure device), the semiconductor wafer 1 is exposed by plural shots while stepping the wafer repeatedly, thus requiring alignment for each shot.

FIG. 7 is a plan view showing an area which is exposed by one shot in an exposure step in a photolithography process. In FIG. 7 there is shown a shot area 11 which is exposed by one shot in an exposure step in a photolithography process on the main surface of the semiconductor wafer 1. FIG. 7 shows an example in which eight semiconductor chip regions 2 are exposed by one shot. However, the number of semiconductor chip regions 2 exposed by one shot is not limited thereto, but various changes may be made. For example, semiconductor chip regions 2 arranged in several to ten rows in X direction and two rows in Y direction can be exposed by one shot. In this case, about ten to thirty semiconductor chip regions 2 are exposed by one shot.

With the recent tendency to microstructurization and high integration of semiconductor devices, it is required to enhance the alignment accuracy in the exposure step. Therefore, in the exposure step it is preferable alignment be performed in two directions intersecting (orthogonal to) each other. This is advantageous to improvement of the alignment accuracy and microstructurization and high integration of semiconductor devices.

In this embodiment, therefore, as alignment patterns there are used two types of alignment patterns for making alignment in two directions, i.e., a first alignment pattern 13a and a second alignment pattern 13b. The first and second alignment patterns 13a, 13b are for alignment in different directions. The first alignment pattern 13a is used for alignment in X direction, while the second alignment pattern 13b is used for alignment in Y direction.

Each alignment pattern indicates an alignment pattern (pattern for alignment, alignment mark, alignment target) used for example in a photolithography process (exposure step). The alignment pattern is formed for example by a concave or convex pattern in the semiconductor substrate area, insulating film, semiconductor film or conductive film (metallic film). It can be formed in a scribing region 3 so as not to affect the semiconductor integrated circuit formed in each semiconductor chip region 2.

In this embodiment, the first alignment pattern (alignment pattern-formed region) 13a is an alignment pattern for making alignment in X direction (or a region where an alignment pattern for making alignment in X direction is formed). The second alignment pattern 13b is an alignment pattern for making alignment in Y direction intersecting (orthogonal to) X direction (or a region where an alignment pattern for making alignment in Y direction is formed) . One of the first and second alignment patterns 13a, 13b has a pattern shape substantially corresponding to a 90° rotated pattern with respect to the other.

As shown in FIGS. 2 to 4, the scribing regions include first scribing regions 3a extending in X direction (first direction) and second scribing regions 3b extending in Y direction (second direction) intersecting (orthogonal to) X direction.

The first scribing regions 3a are each positioned between and in contact with short sides 5 of semiconductor chip regions 2 which are adjacent to each other in Y direction. The second scribing regions 3b are each positioned between and in contact with long sides 4 of semiconductor chip regions 2 which are adjacent to each other in X direction.

The X direction in which the first scribing regions 3a extend is parallel to the short sides 5 of the semiconductor chip regions 2, while the Y direction in which the second scribing regions 3b extend is parallel to the long sides 4 of the semiconductor chip regions 2. Since the semiconductor chip regions 2 each have a rectangular plane shape, X and Y directions are orthogonal to each other.

In this embodiment, as is seen also from FIGS. 3, 4 and 7, the width (size in X direction) W2 of each second scribing region 3b is smaller than the width (size in Y direction) W1 of each first scribing region 3a, (i.e., W2<W1). All the alignment patterns used in the photolithography processes in the wafer process of step S2 are formed in the first scribing regions 3 and not formed in the second scribing regions 3b. As noted above, as the alignment patterns used in the photolithography processes there are two types of alignment patterns which are the first alignment pattern 13a and the second alignment pattern 13b. The two types of alignment patterns (the first and second alignment patterns 13a, 13b) are formed in the first scribing regions 3a and not formed in the second scribing regions 3b. Therefore, in the photomask (reticle) used in the exposure step, the width of the region corresponding to each second scribing region 3b is smaller (narrower) than the width of the region corresponding to each first scribing region 3a and the patterns corresponding to the first and second alignment patterns 13a, 13b are all formed in the regions corresponding to the first scribing regions 3a and not formed in the regions corresponding to the second scribing regions 3b.

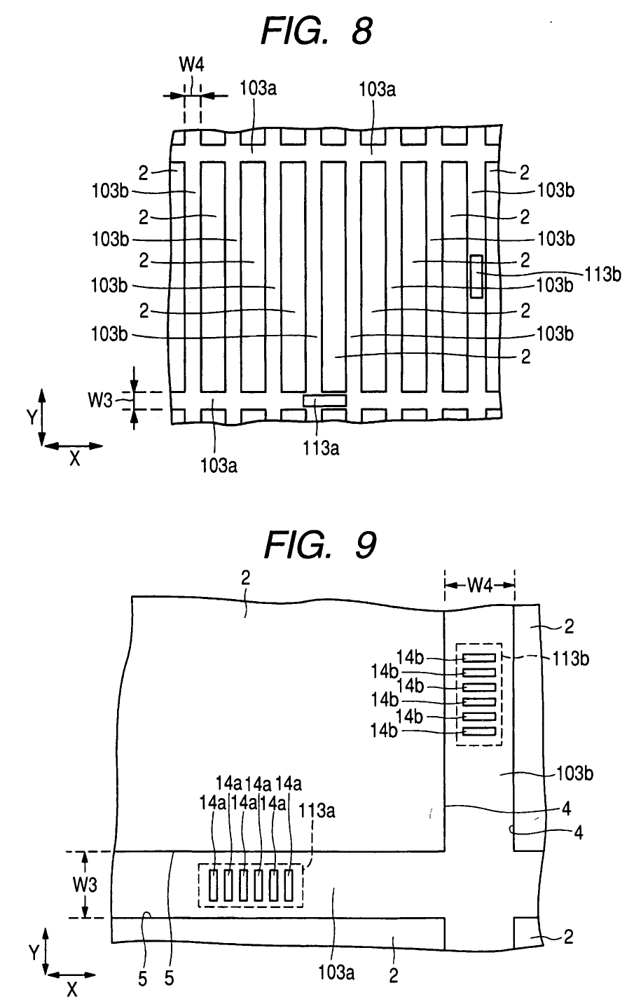

FIGS. 8 and 9 are plan views of principal portions of a semiconductor wafer in a semiconductor device manufacturing process as a comparative example, corresponding to FIGS. 3 and 4, respectively.

In the comparative example shown in FIGS. 8 and 9 (hereinafter referred to simply as the comparative example), the same semiconductor chip regions 2 as in this embodiment are disposed (arranged) in two dimensions (in both Y and Y directions) regularly side by side on a main surface of a semiconductor wafer, and scribing regions 103 are provided each between adjacent semiconductor chip regions 2. The scribing regions 103, which correspond to the scribing regions 3 in this embodiment, include first scribing regions 103a (corresponding to the first scribing regions 3a in this embodiment) extending in a direction (X direction) parallel to short sides 5 of the semiconductor chip regions 2 and second scribing regions 103b (corresponding to the scribing regions 3b in this embodiment) extending in a direction (Y direction) parallel to long sides 4 of the semiconductor chip regions 2.

In the comparative example, the width W3 of each first scribing region 103a and the width W4 of each second scribing region 103b are equal to each other (W3=W4). Of alignment patterns used in photolithography processes, a first alignment pattern 113a (corresponding to the first alignment pattern 13a in this embodiment) is formed in a first scribing region 103a, while a second alignment pattern 113b (corresponding to the second alignment pattern 13b in this embodiment) is formed in a second scribing region 103b. According to the comparative example, therefore, in a photomask (reticle) used in the exposure step, the width of the region corresponding to the first scribing region 103a is equal to the width of the region corresponding to the second scribing region 103b and a pattern corresponding to the first alignment pattern 113a is formed in the region corresponding to the first scribing region, while a pattern corresponding to the second alignment pattern 113b is formed in the region corresponding to the second scribing region 103b.

The first alignment pattern (alignment pattern-formed region) 113a is an alignment pattern (or an alignment pattern-formed region) for making alignment in X direction, while the second alignment pattern (alignment pattern-formed region) 113b is an alignment pattern (or an alignment pattern-formed region) for making alignment in Y direction. One of the first and second alignment patterns 113a, 113b has a pattern shape substantially corresponding to a 90° rotated pattern with respect to the other. Therefore, the first and second alignment patterns 113a, 113b have almost the same size and the first alignment pattern 113a extends long in X direction, while the second alignment pattern 113b extends long in Y direction. That is, the first alignment pattern 113a or its formed region is longer in X direction than in Y direction, while the second alignment pattern 113b or its formed region is longer in Y direction than in X direction. Consequently, as in the comparative example shown in FIGS. 8 and 9, the first alignment pattern 113a extending in X direction is usually provided in the first scribing region 103a extending in X direction, while the second alignment pattern 113b extending in Y direction is usually provided in the second scribing region 103b extending in Y direction.

In the comparative example shown in FIGS. 8 and 9, the alignment accuracy in the exposure step can be improved by forming two types of alignment patterns for alignment in two directions (X and Y directions), i.e., the first alignment pattern 113a and the second alignment pattern 113b, in scribing regions. However, in the comparative example shown in FIGS. 8 and 9, the first alignment pattern 113a is formed in the first scribing region 103a, while the second alignment pattern 113b is formed in the second scribing region 103b. Therefore, it is necessary that the width W3 of the first scribing region 103a be set larger than the size in Y direction of the first alignment pattern 113a and that the width W4 of the second scribing region 103b be set larger than the size in X direction of the second alignment pattern 113b. In this connection, a limit is encountered in reducing the width W3 of the first scribing region 103a and the width 103b of the second scribing region 103b and therefore a limit is encountered in increasing the number of semiconductor chip regions 2 capable of being formed on the semiconductor wafer, i.e., the number of semiconductor chips 12 capable of being obtained from one semiconductor wafer.

On the other hand, in the wafer process of step S2 according to this embodiment, as shown in FIGS. 3, 4 and 7, all the alignment patterns (i.e., the first and second alignment patterns 13a, 13b) used in photolithography processes are formed in the first scribing regions 3a and not formed in the second scribing regions 3b. That is, in the wafer process of step S2, two types of alignment patterns (first and second alignment patterns 13a, 13b) used in photolithography processes are formed in the first scribing regions and not formed in the second scribing regions 3b.

Since the first alignment pattern 13a is an alignment pattern (or an alignment pattern-formed region) for making alignment in X direction, like the first alignment pattern 113a in the comparative example, the first alignment pattern 13a or its forming region is longer in X direction than in Y direction. Since the second alignment pattern 13b is an alignment pattern (or an alignment pattern-formed region) for making alignment in Y direction, like the alignment pattern 113b in the comparative example, the second alignment pattern 13b or its forming region is longer in Y direction than in X direction. In this embodiment, not only the first alignment pattern 13a extending long in X direction but also the second alignment pattern 13b extending long in Y direction is formed in the first scribing region 3a extending in X direction, so there arises the necessity that the width W1 of the first scribing region 3a be set larger than the width W3 of the first scribing region 103a in the comparative example.

Instead, in this embodiment no alignment pattern is formed in the second scribing region 3b. That is, since neither the first alignment pattern 13a nor the second alignment pattern 13b is formed, the width W2 of the second scribing region 3b can be made smaller than the width W4 of the second scribing region 103b in the comparative example (W2<W4). Consequently, the width W2 of the second scribing region 3b becomes narrower than the width W1 of the first scribing region 3a (W2<W1). For example, the width W1 of the first scribing region 3a can be set at about 200 μm (W1 =200 μm) and the width W2 of the second scribing region 3b can be set at about 50 μm (W2=50 μm) or less.

Since the first alignment pattern 13a is formed for alignment in X direction, it is formed for example by patterns arranged repeatedly in X direction in the first scribing area 3a. Since the second alignment pattern 13b is used for alignment in Y direction, it is formed for example by patterns arranged repeatedly in Y direction in the first scribing region 3a. For example, as illustrated in FIG. 4, in the first scribing region 3a, the first alignment pattern 13a has a pattern configuration such that plural patterns (concave or convex patterns) 14a each having dimensions of about 4 μm in X direction and about 50 μm in Y direction are arranged in X direction at intervals of about 20 to 20 μm. As a whole, the first alignment pattern 13a has dimensions of about 140 μm in X direction and about 50 μm in Y direction. Further, as illustrated in FIG. 4, in the first scribing region 3a, the second alignment pattern 13b has a pattern configuration such that plural patterns (concave or convex patterns) each having dimensions of about 4 μm in Y direction and about 50 μm in X direction are arranged at intervals of about 10 to 20 μm. As a whole, the second alignment pattern 13b has dimensions of about 50 μm in X direction and about 140 μm in Y direction.

Thus, the first and second alignment patterns 13a, 13b have almost equal dimensions due to a mutually rotated relation by 90°. That is, the dimension D1 in X direction of the first alignment pattern 13a or its forming region is almost equal to the dimension D2 in Y direction of the second alignment pattern 13b or its forming region (D1=D2) and the dimension in Y direction of the first alignment pattern 13a or its forming region is almost equal to the dimension D3 in X direction of the second alignment pattern 13b or its forming region.

In this embodiment there arises the necessity of enlarging the with W1 of the first scribing region 3a, but since the dimension D2 in Y direction of the second alignment pattern 13b is set almost equal to the second alignment pattern 113b in the comparative example without reducing it, it is possible to prevent deterioration of the alignment accuracy in Y direction utilizing the second alignment pattern 13b even if the second alignment pattern is formed in the first scribing region 3a. That is, in this embodiment, the first and second alignment patterns 13a, 13b formed in the first scribing region 3a are made almost equal in size because of a mutually rotated relation by 90°, whereby it is possible to enhance the alignment accuracy in both X and Y directions.

In the comparative example shown in FIGS. 8 and 9 it is necessary that the width W4 of the second scribing region 103b be set larger than the dimension in X direction of the second alignment pattern 113b because the second alignment pattern 113b is formed in the second scribing region 103b. In this embodiment, however, since both first and second alignment patterns 13a, 13b are formed in the first scribing region 3a, it is possible to narrow the width W2 of the second scribing region 3b. For example, the width W2 of the second scribing region 3b can be set equal to or smaller than the dimension D3 in X direction of the second alignment pattern 13b (e.g., the dimension in X direction of each pattern 14b), (W2≦D3).

Each semiconductor chip region 2 (and a semiconductor chip 12 formed therefrom) has a rectangular outline having long sides 4 and short sides 5 shorter than the long sides. In the case where the semiconductor chip 12 is a semiconductor chip for LCD (liquid crystal display) driver, for example each long side 4 can be set at about 12 mm and each short side at about 1 mm. Each long side 4 has a dimension several times or more as large as each short side 5. Consequently, as is seen also from FIG. 2, the number of semiconductor chip regions 2 arranged in X direction on the main surface of the semiconductor wafer 1 is larger than that of semiconductor chip regions 2 arranged in Y direction on the wafer main surface. That is, on the main surface of the semiconductor wafer 1, the number of second scribing regions 3b extending in Y direction is larger than that of first scribing regions 3a extending in X direction. Therefore, as in this embodiment, even if the width W1 of each first scribing region 3a becomes larger as a result of arranging not only first alignment patterns 13a but also second alignment patterns 13b in the first scribing regions, the width W2 of each second scribing region 3b is narrowed because no alignment pattern is formed in the second scribing region 3b, whereby the total number of semiconductor chip regions 2 arranged on the main surface of the semiconductor wafer 1 can be increased. Consequently, it is possible to increase the total number (the number of acquisition, the number of chips acquired) of semiconductor chips 12 capable of being acquired from one semiconductor wafer 1 and hence possible to decrease the manufacturing cost of each semiconductor chip 12.

For example, if semiconductor chips (corresponding to the semiconductor chips 12) are produced with use a semiconductor wafer of 8 inches in diameter as the semiconductor wafer 1 and by application of the comparative example shown in FIGS. 8 and 9, the number of semiconductor chips capable of being acquired from one semiconductor wafer is about 2000. On the other hand, if semiconductor chips 12 are produced by application of this embodiment, the number of semiconductor chips 12 capable of being acquired from one semiconductor wafer can be increased to about 2200 (an increase of 10%).

On the main surface of the semiconductor wafer 1 a plurality of first scribing regions 3a extend in X direction and a plurality of second scribing regions 3b extend in Y direction, but it is preferable that the plural first scribing regions 3a have the same size of width W1 and the plural second scribing regions 3b have the same size of width W2. Likewise, on the main surface of the semiconductor wafer 1 a plurality of semiconductor chip regions 2 are arranged in a matrix shape in both X and Y directions, but it is also preferable for the plural semiconductor chip regions 2 to be equal in size. As a result, on the main surface of the semiconductor wafer 1, the semiconductor chip regions 2 can be arranged at equal pitches (equal intervals) in X direction and at equal pitches (equal intervals) in Y direction. Consequently, it is possible to facilitate execution of an inspection process (e.g., probe test) which is performed after the wafer process of step S2 and before the dicing process of step S3.

Although in connection with the wafer process of step S2 a description has been given above about alignment patterns (13a, 13b) used in photlithography processes (exposure steps) for which a high alignment accuracy is particularly required, this is also true of alignment patterns used in other processes than the lithography processes. That is, alignment patterns used in other processes than the photolithography processes (exposure steps) in the wafer process of step S2 are all formed in the first scribing regions 3a and not formed in the second scribing regions 3b. Therefore, with respect to the alignment patterns used other processes than the photolithography processes (exposure steps) in the wafer process of step S2, if there are two types of alignment patterns for making alignment in two directions like the first and second alignment patterns 13a and 13b, all of them are formed in the first scribing regions 3a and not formed in the second scribing regions 3b.

In case of using a stepper (a stepping type exposure device), the semiconductor wafer 1 is exposed by plural shots while stepping the semiconductor wafer 1 repeatedly. Therefore, alignment is performed in two directions (X and Y directions) for each shot and it is necessary to use both first and second alignment patterns 13a, 13b for each shot (one shot region) . Therefore, as shown in FIG. 7, the first and second alignment patterns 13a, 13b are formed for each shot region (the region exposed by one shot in the exposure step in each photolithography process).

Thus, in this embodiment, since two types of alignment patterns, i.e., the first and second alignment patterns 13a, 13b, for making alignment in two directions (X and Y directions) are formed in the scribing regions 3, it is possible to improve the alignment accuracy, which is advantageous to microstructurization and high integration of the resulting semiconductor devices. Moreover, since all the alignment patterns, including the first and second alignment patterns, are disposed in the first scribing regions 3a and not disposed at all in the second scribing regions 3b, it is possible to narrow the width W2 of each second scribing region 3b and hence possible to increase the total number of semiconductor chips 12 capable of being obtained from one semiconductor wafer 1 and thereby decrease the manufacturing cost of the semiconductor chips 12. Consequently, it becomes possible to attain both improvement of the alignment accuracy and reduction of the semiconductor device manufacturing cost.

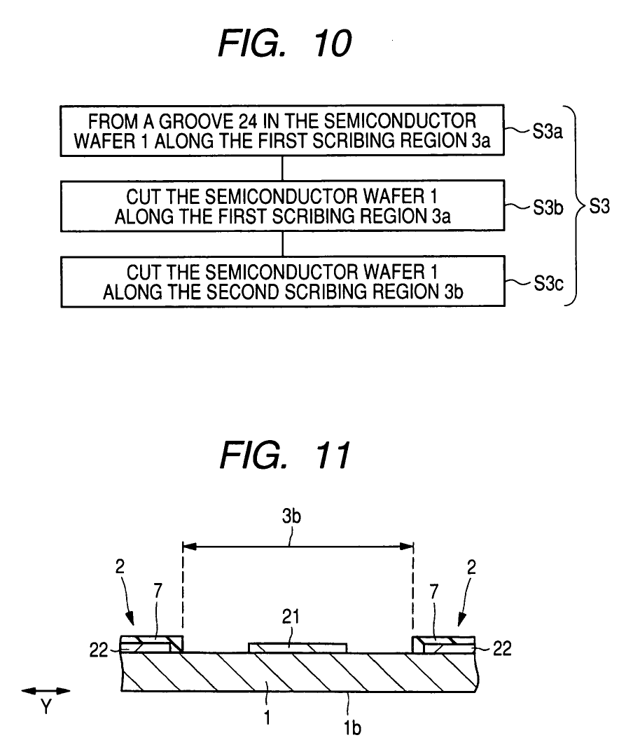

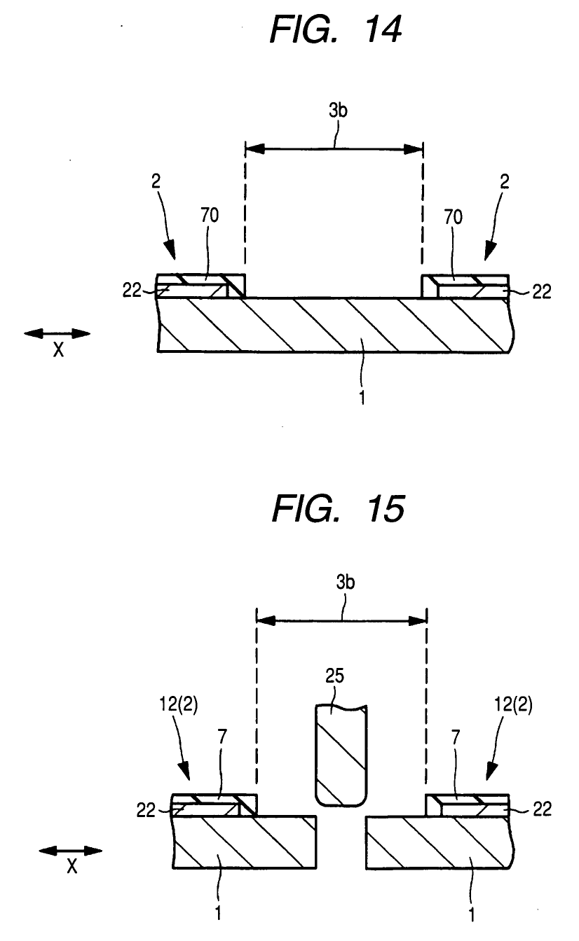

Next, a more detailed description will be given about the dicing (cutting) process of step S3 for the semiconductor wafer 1 in this embodiment. FIG. 10 is a manufacturing process flow chart showing the dicing process of step S3 in more detail. FIGS. 11 to 15 are explanatory sectional views of a principal portion in the dicing process of step S3 for the semiconductor wafer 1, of which FIGS. 11 to 13 show a section (a section near a first scribing region 3a) perpendicular to X direction and parallel to Y direction and FIGS. 14 and 15 show a section (a section near a second scribing region 3b) perpendicular to Y direction and parallel to X direction.

FIG. 11 is a sectional view of a principal portion near a first scribing region 3a on the semiconductor wafer 1 after execution of the wafer process of step S2. A back surface (a main surface on the side opposite to the semiconductor element forming region 6 side) 1b of the semiconductor wafer 1 is affixed to a dicing tape (not shown) for example.

As described above, the first and second alignment patterns 13a, 13b are formed in the first scribing regions 3a and various film patterns (concave or convex patterns) are used as the first and second alignment patterns 13a, 13b by the exposure step. Patterns of metallic layers used as wiring layers are also used as the first and second alignment patterns 13a, 13b. Thus, alignment patterns 21 which are metallic layer patterns (metal patterns) are also formed as the first and second alignment patterns 13a, 13b in the first scribing regions 3a.

Metal patterns 22 in the same layer as the alignment patterns 21 are also formed as wiring layers in the semiconductor chip regions 2. In FIG. 11, the illustration of semiconductor element regions 6 is omitted instead of showing metal patterns 22 in semiconductor chip regions 2 schematically, and the metal patterns 22 are each covered with a protective film.

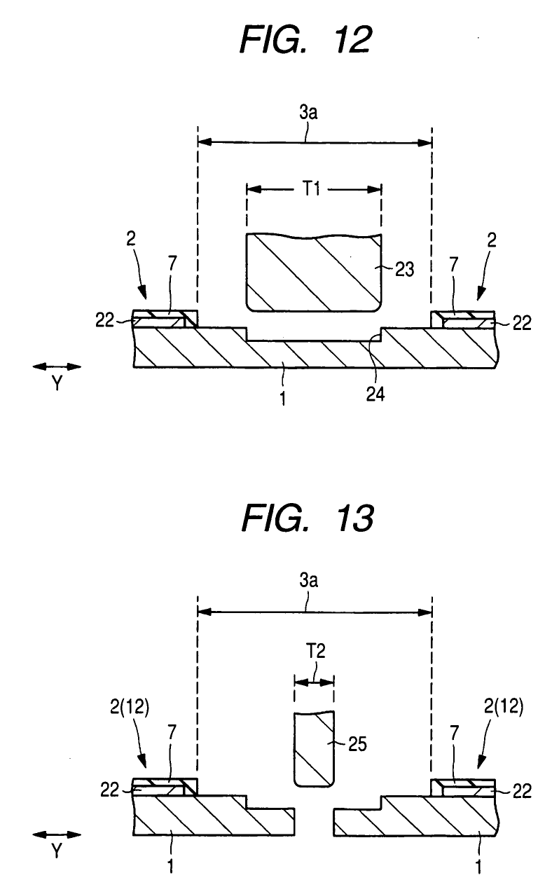

For the dicing of step S3, as shown in FIG. 12, first a groove (concave groove) 24 is formed in the semiconductor wafer 1 along the first scribing region 3a with use of a blade (dicing blade, dicing saw, cutting edge) 23 (step S3a).

In step S3a there is performed half-cutting such that the semiconductor wafer 1 is not cut completely, but only the upper portion of the wafer is cut in the first scribing region 3a, allowing the lower portion of the wafer to remain. In this way the groove 24 is formed along the first scribing region 3a. In this case, the alignment pattern 21 is removed from the first scribing region 3a so as not to remain in the first scribing region. Therefore, the blade 23 has a large thickness Ti which is sufficient for removing the alignment pattern 21 from the first scribing region 3a. The width (width in Y direction) of the groove 24 formed substantially corresponds to the thickness T1 of the blade 23. Cutting (dicing) of the second scribing region 3b is not performed in step S3a.

Next, with use of a blade (dicing blade, dicing saw, cutting edge) 25, as shown in FIG. 13, the semiconductor wafer 1 is cut at the bottom of the groove 24 along the first scribing region 3a (step S3b). The thickness (width) T2 of the blade 25 used is smaller than the thickness (width) T1 of the blade 23, (i.e., T2<T1). In step S3b, the semiconductor wafer 1 is cut completely in the first scribing region 3a, that is, full-cutting is performed. Consequently, in step S3b, the semiconductor wafer 1 is cut at the bottom of the groove 24 over a width smaller than the width of the groove 24.

Next, as shown in FIGS. 14 and 15, the semiconductor wafer 1 is cut along the second scribing region 3b with use of the blade 25 (step S3c). FIG. 14 shows a state before cutting the second scribing region 3b and FIG. 15 shows a state after cutting the semiconductor wafer 1 along the second scribing region 3b in step S3c.

In step 3c there may be used the same blade 25 as that used in step S3b. In step S3c there is performed full-cutting to cut the semiconductor wafer 1 completely along the second scribing region 3b. Step S3c may be carried out before step S3b. Dicing of the semiconductor wafer 1 in step S3 is performed by steps S3a, S3b and S3c, whereby the semiconductor wafer 1 is divided into individual semiconductor chips 12.

In this embodiment, for cutting the semiconductor wafer 1 along each first scribing region 3a, first in step S3a, half-cutting is performed using the blade 23 of the large thickness T1 to form a groove 24, then full-cutting is performed using the blade 25 smaller in thickness than the blade 23 to cut the semiconductor wafer 1 at the bottom of the groove 24. That is, two-stage operations of steps S3a and S3b are performed for cutting (dicing) the semiconductor wafer 1 along the first scribing 3a. Further, for cutting the semiconductor wafer 1 along each second scribing region 3b, full-cutting is performed using the blade 25 smaller in thickness than the blade used in step S3c. That is, a one-stage operation is performed in step S3c to cut (dice) the semiconductor wafer 1 along the second scribing region 3b. Thus, the semiconductor wafer 1 is cut in the two steps of S3a and S3b along the first scribing region 3a and is cut in the one step of S3c along the second scribing region 3b. That is, three-step operations (dicing operations) of steps S3a to S3c are performed for dicing the semiconductor wafer 1 into plural semiconductor chips.

Unlike this embodiment, if step S3a is omitted and only the full-cutting operation using the thin blade 25 is performed for cutting the semiconductor wafer 1 along the first scribing regions 3a, there is a possibility that the alignment patterns 21 formed by metal patterns may partially remain at ends of the semiconductor chips 12 after the dicing process of step S3. Particularly, when not only the alignment patterns 13a but also the second alignment patterns 13b are formed in the first scribing regions 3a as described earlier, the alignment patterns 21 corresponding to the second alignment patterns 13b in the first scribing regions 3a become larger in size in Y direction, so that even if dicing is performed, the alignment patterns 21 corresponding to the second alignment patterns 13b are not completely removed and apt to remain partially. If there are metal residues at ends of the semiconductor chips 12, there arises the possibility that a short-circuit between terminals may occur at the time of subsequent packaging of the semiconductor chips 12.

Unlike this embodiment, if step S3b is omitted and step S3a is performed by full-cutting, that is, if only the full-cutting operation using the thick blade 23 is performed for cutting the semiconductor wafer 1 along the first scribing regions 3a , chipping is apt to occur because the thick blade 23 is used for full-cutting.

On the other hand, in this embodiment, half-cutting is performed along the first scribing regions 3a of the semiconductor wafer 1 with use of the thick blade 23 in step S3a to form grooves 24, thereby removing the alignment patterns 21 from the first scribing regions 3a. Consequently, the alignment patterns 21 formed by metal patterns can be prevented from remaining at ends of the semiconductor chips after the dicing process of step S3. Particularly, in the first scribing regions 3a the alignment patterns 21 corresponding to t he second alignment patterns 13b become large in size in Y direction, but in step S3a the alignment patterns 21 in the first scribing regions 3a can be removed completely by using the blade 23 thicker than the size in Y direction of the alignment patterns 21. That is, all of the first and second alignment patterns 13a, 13b, including the alignment patterns 21, are removed. As a result, it is possible to prevent any metal residue from being present at ends of the semiconductor chips 12 and hence possible to prevent the occurrence of a short-circuit between terminals when packaging the semiconductor chips 12.

Further, after step S3a in this embodiment, the bottom of the groove 24 in each first scribing region 3a of the semiconductor wafer 1 is cut (full-cut) using the thin blade 25 in step S3b, whereby the semiconductor wafer 1 can be cut while presenting the occurrence of chipping. In this embodiment, since no alignment pattern is formed in the second scribing regions 3b of the semiconductor wafer 1, alignment patterns 21 as metal patterns are not formed. Therefore, in step S3c, the second scribing regions 3b of the semiconductor wafer 1 are full-cut using the thin blade 25, whereby the semiconductor wafer 1 can be cut while preventing the occurrence of chipping and it is possible to improve the manufacturing yield of the resulting semiconductor devices (semiconductor chips 12). Besides, in the second scribing regions 3b there is formed nothing corresponding to the grooves 24, so that the semiconductor wafer 1 can be cut along the second scribing regions 3b by a single-stage operation and hence it is possible to prevent an increase in the number of semiconductor device manufacturing steps. It is preferable that the same blade 25 be used in both steps S3b and S3c, whereby both steps S3b and S3c can be carried out without replacing the blade 25 in the dicing device and therefore it is possible to improve the throughput and shorten the time required for the dicing process.

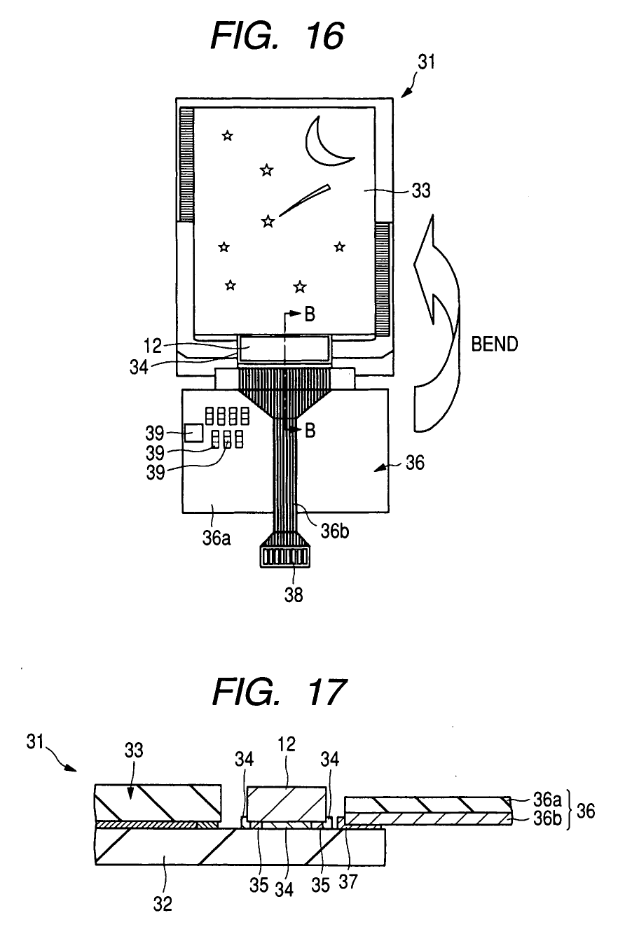

The following description is now provided about a working example of a semiconductor chip (semiconductor device) 12 manufactured according to this embodiment. FIG. 16 is a plan view (explanatory view) showing a mounted state of the semiconductor chip 12 to an LCD (liquid crystal display) panel (liquid crystal panel) and FIG. 17 is a sectional view of a principal portion thereof. The section taken on line B-B in FIG. 16 substantially corresponds to FIG. 17.

Each semiconductor chip 12 fabricated in the above manner (steps S1 to S3) is used in a mounted state to an LCD panel or the like as shown schematically in FIGS. 16 and 17.

In an LCD panel 31, as shown in FIGS. 16 and 17, an LCD portion 33 is provided on a main surface of a glass substrate (glass plate) 32. The LCD portion 33 has a structure such that a liquid crystal material (an oily 42, transparent liquid crystal composition) is sandwiched in between the glass substrate 32 and another glass substrate (the glass substrate shown as the LCD portion 33) and sealing is made along the outer periphery. On inner surfaces of the glass substrates there are provided electrodes (transparent electrodes) for the application of voltage to the liquid crystal. A polarizing filter may be provided on a back surface of the glass substrate 32 and a lens filter (filter) may be provided on a surface of the glass substrate which constitutes the LCD portion.

The semiconductor chip 12 is mounted and fixed to an end portion of the main surface of the glass substrate 32 through an ACF (Anisotropic Conductive Film) 34. Electrodes 35 on the semiconductor chip 12 are electrically connected each through the ACF 34 to terminals formed on the main surface of the glass substrate 32. The electrodes 35 on the semiconductor chip 12 correspond to pad electrodes 8 shown in FIG. 5 or to bump electrodes formed on the pad electrodes. An FPC (flexible printed circuit board, flexible wiring board) 36 is joined to a further end portion of the glass substrate 32 through an ACF 37 and conductor patterns 36b (terminal constituting portions) of FPC 36 are electrically connected to terminals formed on the main surface of the glass substrate 32. The FPC 36 is made up of an insulating base film (insulating layer) 36a and the conductor patterns 36b formed thereon, having flexibility. Therefore, the electrodes 35 of the semiconductor chip 12 are electrically connected to terminals (conductor patterns 36b) of the FPC 36 via ACF 34, terminals and wiring lines formed on the main surface of the glass substrate 32 and ACF 37 and are further connected electrically to external terminals 38 of the FPC 36 via wiring lines formed by the conductor patterns 36b of the FPC 36. Where required, chip parts 39 such as chip capacitors are mounted on the FPC 36. The size of the LCD panel 31 or LCD module can be reduced by bending the FPC 36 to a back surface side of the LCD panel 31, as shown schematically with an arrow in FIG. 16.

The semiconductor chip 12 is mounted near an end portion of the main surface of the glass substrate 32 of the LCD panel 31 so as to extend along a side face of the glass substrate 32 and is used for the LCD driver of the LCD panel or LCD module. If the semiconductor chip 12 for the LCD driver is disposed so that its long sides 4 are approximately parallel to a side of the glass substrate 32, then it suffices for the chip long sides 4 to be smaller than the side of the glass substrate 331, therefore, even an increase in length of each long side 4 of the semiconductor chip 12 does not act to increase the size of the LCD panel 31 itself. However, if the short sides of the semiconductor chip 12 for the LCD driver are long, this acts to increase the size of the other area than the display area in the LCD panel 31. For this reason it is preferable that the chip short sides 5 be as short as possible. As the short sides 5 become shorter, there arises the necessity of lengthening the long sides 4 in order to ensure the area required for forming the same semiconductor integrated circuit. Thus, in the semiconductor chip 12 for the LCD driver, the long sides 4 are fairly larger than the short sides 5, that is, the ratio of each long side 4 to each short side 5 is fairly large. For example, each long side 4 can be set at about 12 mm and each short side 5 at about 1 mm, the former being several times or more larger in size than the latter.

In this embodiment, all the alignment patterns are formed in the first scribing regions 3a and not formed in the second scribing regions 3b, whereby even if the width W1 of each first scribing region 3a becomes large, it is possible to narrow the width W2 of each second scribing region 3b. Therefore, on the main surface of the semiconductor wafer 1, the number of semiconductor chip regions 2 arranged in X direction parallel to the short sides 5 is increased to increase the number of semiconductor chips 12 capable of being acquired from the semiconductor wafer. In case of fabricating a semiconductor chip 12 having a large long side 4 to short side 5 ratio like the semiconductor chip for LCD driver, the number of the second scribing regions 3b on the main surface of the semiconductor wafer 1 becomes very large, so that the effect of increase in the number of semiconductor chips 12 acquired from the semiconductor wafer as a result of narrowing the width W2 of each second scribing region 3b becomes more outstanding. Therefore, if this embodiment is applied to the manufacture of a semiconductor chip 12 having a large long side 4 to short side 5 ratio like the semiconductor chip for LCD driver, the effect obtained is more outstanding.

This embodiment is applicable by only changing the design of the scribing regions 3 without changing the design of the scribing regions 3. Thus, this embodiment can be applied by merely providing a photomask based on a changed design of scribing regions, without the need of changing circuit patterns in the regions corresponding to the semiconductor chips 2 in the photomask. Thus, the design and fabrication of the photomask newly provided are easy. Therefore, it is easy to apply this embodiment to existing semiconductor device manufacturing process and equipment.

### Second Embodiment

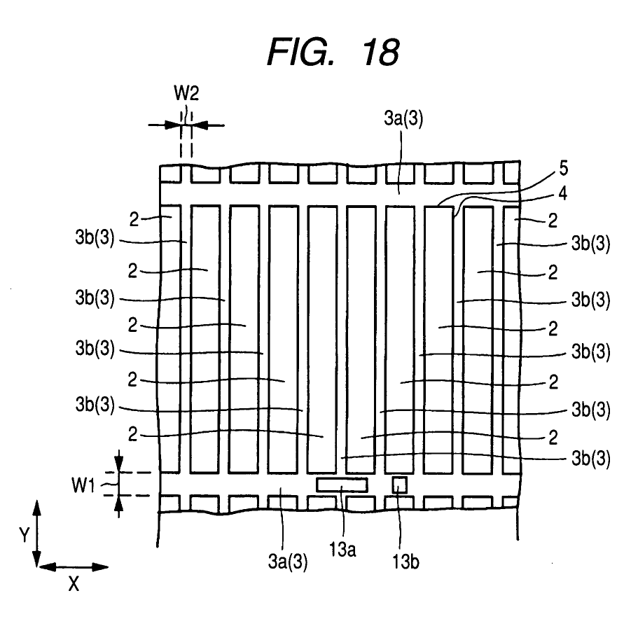

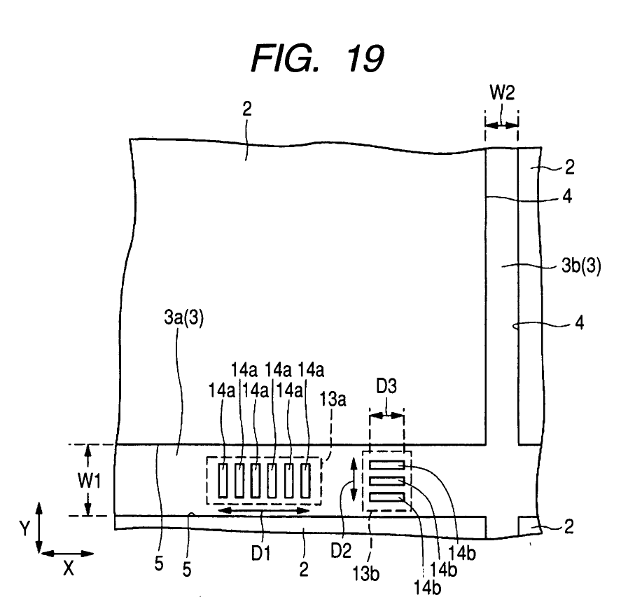

FIG. 18 is a plan view of a principal portion of a semiconductor wafer in a semiconductor device manufacturing process according to a second embodiment of the present invention and FIG. 19 is a plan view of a principal portion of the semiconductor wafer, showing alignment pattern-formed regions and the vicinity thereof on a larger scale.

As shown in FIGS. 18 and 19, also in this embodiment, as in the previous first embodiment, alignment patterns (i.e., first and second alignment patterns 13a, 13b) used in each photolithography process are all formed in first scribing regions 3a and not formed in second scribing regions 3b.

In the above first embodiment, however, as shown in FIGS. 3 and 4, since the second alignment pattern 13b of the same size as the second alignment pattern 113b in the comparative example is formed in the first scribing region 3a, it is necessary that the second alignment pattern 13b or its formed region be long in Y direction and that the width W1 of the first scribing region 3a be larger than the width W3 of the first scribing region 103a in the comparative example.

On the other hand, in this embodiment, as shown in FIGS. 18 and 19, the second alignment pattern 13b is an alignment pattern (or an alignment pattern-formed region) for making alignment in Y direction, but its size in Y direction is set short (small) in comparison with the second alignment pattern 113b in the above comparative example so that it can be formed in the first scribing region 3a extending in X direction. That is, although in the first embodiment the dimension D1 in X direction of the first alignment pattern 13a is almost equal to the dimension D2 in Y direction of the second alignment pattern 13b (D1=D2), in this second embodiment the dimension D2 in Y direction of the second alignment pattern 13b is set smaller than the dimension D1 in X direction of the first alignment pattern 13a (D1>D2). Therefore, even if both first and second alignment patterns 13a, 13b are formed in the first scribing region 3a, it is not necessary to increase the width W1 of the first scribing region 3a. For example, in this embodiment the width W1 of the first scribing region 3a can be set almost equal to the width W3 of the first scribing region 103a in the comparative example (W1=W3).

For example, also in this embodiment, as in the first embodiment, as shown in FIG. 19, the first alignment pattern 13a in the first scribing region 3a has a pattern structure such that plural patterns (concave or convex patterns) 14a each having a dimension in X direction of about 4 μm and a dimension in Y direction of about 50 μm are arranged in X direction at intervals of about 10 to 20 μm. As a whole, the first alignment pattern 13a has dimensions of about 140 μm in X direction and about 50 μm in Y direction. In the first scribing region 3a, the second alignment pattern 13b has a pattern structure such that plural patterns (concave or convex patterns) having a dimension in Y direction of about 4 μm and a dimension in X direction of about 50 μm are arranged in Y direction at intervals of about 10 to 20 μm. But in this embodiment the number of arranged patterns 14b is smaller than in the first embodiment. Therefore, as a whole, the dimension D2 in Y direction of the second alignment pattern 13b is smaller than in the first embodiment and the second alignment pattern 13b has dimensions of about 50 μm in X direction and about 70 μm in Y direction.

Thus, in this second embodiment, the first and second alignment patterns 13a, 13b formed in the first scribing region 3a are in a mutually 90° rotated relation, but have different dimensions. More particularly, the dimension D2 in Y direction of the second alignment pattern 13b or its formed region is smaller than the dimension D1 in X direction of the first alignment pattern 13a or its formed region (D1>D2). On the other hand, the dimension in Y direction of the first alignment pattern 13a or its formed region can be made almost equal to the dimension in X direction of the second alignment pattern 13b or its formed region.

Also in this embodiment, as in the first embodiment, since no alignment pattern is formed in the second scribing region 3b, the width W2 of the second scribing region 3b can be made narrower than the width W4 of the second scribing region 103b in the comparative example (W2<W4). That is, in the comparative example shown in FIGS. 8 and 9 the second alignment pattern 113b is formed in the second scribing region 103b and therefore it is necessary that the width W4 of the second scribing region 103b be set larger than the dimension in X direction of the second alignment pattern 113b. In this second embodiment, however, since both first and second alignment patterns 13a, 13b are formed in the first scribing region 3a, the width W2 of the second scribing region 3b can be made narrow. For example, the width W2 of the second scribing region 3b can be made equal to or smaller than the dimension in X direction of the second alignment pattern 13b (e.g., the dimension in X direction of the pattern 14b) (W2<D3). Consequently, also in this embodiment the width W2 of the second scribing region 3b becomes smaller than the width S1 of the first scribing region 3a (W2<W1) . For example, the width W1 of the first scribing region 3a can be set at about 120 μm (W1=120 μm) and the width W2 of the second scribing region 3b can be set at about 50 μm (W2=50 μm).

Other constructional points and manufacturing process according to this second embodiment are almost equal to those of the first embodiment and therefore an explanation thereof is here omitted.

Also in this second embodiment, as in the first embodiment, two types of alignment patterns (i.e., the first and second alignment patterns 13a, 13b) for making alignment in two directions (X and Y directions) are provided in scribing regions 3, whereby it is possible to improve the alignment accuracy and this is advantageous to microstructurization and high integration of semiconductor devices. Further, all the alignment patterns (i.e., the first and second alignment patterns 13a, 13b) used in photolithography processes are formed in the first scribing regions and not formed in the second scribing regions 3b and the width W2 of each second scribing region 3b is set narrower (than the width W1 of each first scribing region 3a). Consequently, as in the first embodiment, it is possible to increase the number of semiconductor chips 2 arranged in X direction on the main surface of the semiconductor wafer 1 and hence possible to increase the total number of semiconductor chips 12 capable of be acquired from one semiconductor wafer 1 and decrease the manufacturing cost of each semiconductor chip 12. Thus, it becomes possible to attain both improvement of the alignment accuracy and reduction of the semiconductor device manufacturing cost.

In this embodiment, moreover, unlike the first embodiment, the first and second alignment patterns 13a, 13b formed in the first scribing region 3a have different dimensions although both are in a 90° rotated relation to each other and the dimension in Y direction of the second alignment pattern 13b or its formed region is set smaller than the dimension in X direction of the first alignment pattern 13a or its formed region. Consequently, in this embodiment, the width W1 of the first scribing region 3a can be made narrower than in the first embodiment and it is possible to increase the number of semiconductor chips 2 arranged in Y direction on the main surface of the semiconductor wafer 1. As a result, it is possible to further increase the total number of semiconductor chips 12 capable of being acquired from one semiconductor wafer 1 and hence possible to further decrease the manufacturing cost of each semiconductor chip 12.

If the dimension in Y direction of the second alignment pattern 13b or its formed region is made too small, there is a possibility that the alignment accuracy in Y direction utilizing the second alignment pattern 13b may be deteriorated. Therefore, a reduction quantity of the dimension in Y direction of the second alignment pattern 13b or its formed region is determined taking the alignment accuracy required into account and in comparison with the dimension in X direction of the first alignment pattern 13a or its formed region and the width W1 of the first scribing region 3a is determined in accordance with the determined dimension in Y direction of the second alignment pattern 13b or its formed region. By so doing, it is possible to maximize the number of semiconductor chips 12 capable of being acquired from one semiconductor wafer while satisfying the required alignment accuracy. However, when the greatest importance is attached to enhancing the alignment accuracy in each photolithography process for the purpose of attaining microstructurization of each semiconductor device, the application of the previous first embodiment is more preferable.

### Third Embodiment

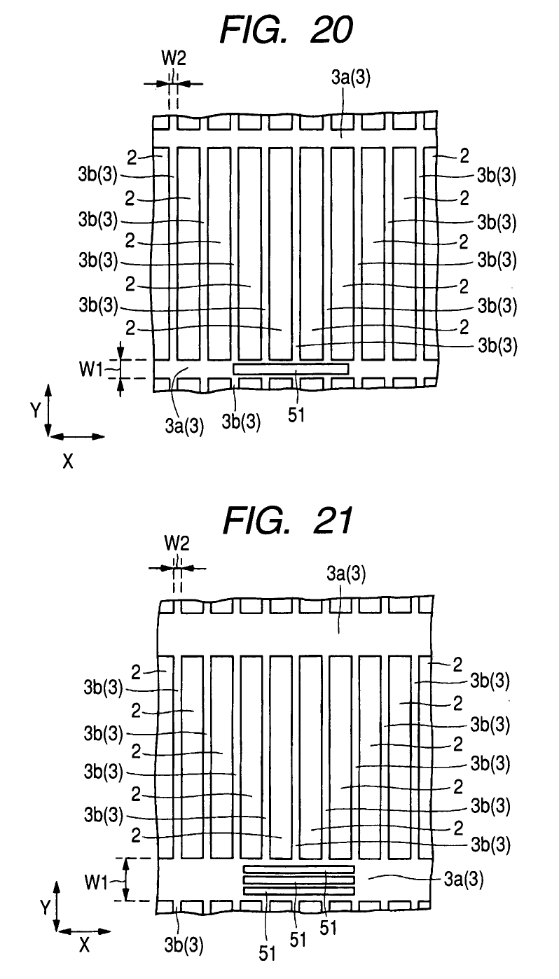

FIGS. 20 and 21 are each a plan view of a principal portion of a semiconductor wafer in a semiconductor device manufacturing process according to a third embodiment of the present invention, each corresponding to FIG. 3 in the first embodiment.

In the previous first and second embodiments a description has been given about the position where alignment patterns are formed. In this third embodiment a description will be given about a TEG pattern forming position. Other constructional points and manufacturing process than TEG pattern are the same as in the first and second embodiments and therefore an explanation thereof is here omitted. Also as to the layout of alignment patterns, it is the same as in the first and second embodiments and therefore first and second alignment patterns 13a, 13b are not shown in FIGS. 20 and 21.

In the wafer process of step S2, in case of forming TEG (Test Element Group) patterns 51, all of them are formed in the first scribing regions 3a of the wafer and not formed in the second scribing regions 3b. The TEG patterns 51 are TEG patterns, test patterns, or QC (Quality Control) patterns, for checking the wafer process. With the TEG patterns 51, it is possible to measure a threshold voltage (Vth) of transistor elements formed, checking an alignment error, or check the film thickness, that is, it is possible to check whether the wafer process is being carried out accurately.

Thus, in the wafer process of step S2, all the patterns to be formed in the scribing regions 3 such as alignment patterns and TEG patterns are formed in the first scribing regions 3a and not formed in the second scribing regions 3b.

In FIG. 20 there is shown an example in which a single TEG pattern is formed in a first scribing region 3a. According to the example shown in FIG. 20, the width W1 of the first scribing region 3a can be prevented from becoming large and this is advantageous to increasing the total number of semiconductor chips 12 capable of being acquired from one semiconductor wafer.

In FIG. 21 there is shown an example in which the width W1 of the first scribing region 3a is made large and plural TEG patterns 51 are arranged side by side in Y direction in the first scribing region 3a. According to the example shown in FIG. 21, the wafer process can be checked more exactly by the TEG patterns 51. In case of arranging the TEG patterns 51 side by side (in one row) in X direction, if the size of each TEG pattern 51 is large, it may be impossible to arrange all the TEG patterns 51 in the first scribing region 3a. However, by enlarging the width W1 of the first scribing region 3a as in FIG. 21 and arranging plural TEG patterns 51 side by side in Y direction in the first scribing region 3a, it becomes possible to arrange all the TEG patterns in the first scribing region 3a.

FIGS. 20 and 21 are applicable to both the first and second embodiments. In the case of FIG. 1, however, it is necessary to make the width W1 of the first scribing region 3a larger than in FIG. 20 and therefore the application thereof to the first embodiment is more preferable.

In this third embodiment, as in the first and second embodiments, in the wafer process of step S2 alignment patterns (i.e., the first and second alignment patterns 13a, 13b) used in photolithography processes are all formed in the first scribing regions 3a and not formed in the second scribing regions 3b. In this embodiment, moreover, in the wafer process of step S2 all the TEG patterns are formed in the first scribing regions and not formed in the second scribing regions 3b. That is, in the wafer process of step S2, patterns to be formed in the scribing regions 3 such as alignment patterns and TEG patterns are all formed in the first scribing regions 3a and not formed at all in the second scribing regions 3b, and the width W2 of each second scribing region 3b is made smaller (than the width W1 of each first scribing region 3a) . As a result, as in the first embodiment, it is possible to increase the number of semiconductor chip regions 2 arranged in X direction on the main surface of the semiconductor wafer 1 and hence possible to increase the total number of semiconductor chips 12 capable of being acquired from one semiconductor wafer 1 and reduce the manufacturing cost of each semiconductor chip.

Although the present invention has been described above concretely by way of embodiments thereof, it goes without saying that the present invention is not limited to the above embodiments, but that various changes may be made within the scope not departing from the gist of the invention.

The present invention is suitably applicable to the semiconductor device manufacturing technique.

What is claimed is:

1. A method of manufacturing a semiconductor device, comprising the steps of:
(a) providing a semiconductor wafer;
(b) forming a semiconductor integrated circuit in each of plural semiconductor chip regions of the semiconductor wafer which regions are to become semiconductor chips later; and
(c) cutting the semiconductor wafer along a scribing region formed between the plural semiconductor chip regions,
wherein the scribing region comprise a first scribing region extending in a first direction and a second scribing region extending in a second direction intersecting the first direction,
wherein the width of the second scribing region is smaller than the width of the first scribing region, and
wherein two types of alignment patterns for use in a photolithography process are formed in the first scribing region, while no alignment pattern is formed in the second scribing region.

2. The method of claim 1, wherein the two types of alignment patterns are alignment patterns to be used for alignment in directions different from each other.

3. The method of claim 3, wherein the two types of alignment patterns are a first alignment pattern to be used for alignment in the first direction and a second alignment pattern to be used for alignment in the second direction.

4. The method of claim 3,
wherein the first alignment pattern comprises patterns arranged repeatedly in the first direction in the first scribing region, and
wherein the second alignment pattern comprises patterns arranged repeatedly in the second direction in the first scribing region.

5. The method of claim 3, wherein one of the first and second alignment patterns is a 90° rotated pattern with respect to the other.

6. The method of claim 3, wherein the size in the first direction of the first alignment pattern and the size in the second direction of the second alignment pattern are the same.

7. The method of claim 3, wherein the size in the second direction of the second alignment pattern is smaller than the size in the first direction of the first alignment pattern.

8. The method of claim 3, wherein the width of the second scribing region is not larger than the size in the first direction of the second alignment pattern.

9. The method of claim 1, wherein the first and the second direction are orthogonal to each other.

10. The method of claim 1,
wherein the semiconductor chip regions each have a rectangular plane shape having long sides and short sides shorter than the long sides,
wherein the first scribing region is in contact with the short sides of the semiconductor chip regions, and
wherein the second scribing region is in contact with the long sides of the semiconductor chip regions.

11. The method of claim 10, wherein the semiconductor chips are semiconductor chips for LCD driver.

12. The method of claim 1,
wherein the semiconductor chip regions each have a rectangular plane shape having long sides and short sides shorter than the long sides,
wherein the first direction is parallel to the short sides of the semiconductor chip regions, and
wherein the second direction is parallel to the long sides of the semiconductor chip regions.

13. The method of claim 1, wherein, in the step (b), a TEG pattern is formed in the first scribing region and not formed in the second scribing region.

14. The method of claim 1, wherein, in the step (b), all of the patterns to be formed in the scribing region are formed in the first scribing region and not formed in the second scribing region.

15. The method of claim 1, wherein the two types of alignment patterns are formed for each area exposed by one shot in an exposure step in a photolithography process.

16. The method of claim 1, wherein the step (c) comprises the steps of:
(c1) forming a groove in the semiconductor wafer along the first scribing region with use of a first blade;
(c2) after the step (c1), cutting the semiconductor wafer at the bottom of the groove along the first scribing region with use of a second blade having a cutting edge thinner than that of the first blade; and
(c3) cutting the semiconductor wafer along the second scribing region.

17. The method of claim 16, wherein the semiconductor wafer is cut along the first scribing region in two steps of the steps (c1) and (c2) and is cut along the second scribing region in one step of the step (c3).

18. The method of claim 16, wherein, in the step (c3), the semiconductor wafer is cut along the second scribing region with use of the second blade.

19. The method of claim 16, wherein, in the step (c1), the semiconductor wafer is half-cut, while in the steps (c2) and (c3) the semiconductor wafer is full-cut.

20. The method of claim 16, wherein the two types of alignment patterns formed in the first scribing region in the step (b) are removed in the step (c1).
